(19) United States
(12) Patent Application Publication
(10) Pub. No.: US 2006/0049970 A1
(43) Pub. Date: Mar. 9, 2006

(54) Sigma-delta modulation

(76) Inventors: Derk Reefman, Eindhoven (NL); Erwin Janssen, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/529,358

(22) PCT Filed: Aug. 8, 2003
(86) PCT No.: PCT/IB03/03656

§ 371 Date: Mar. 25, 2005

(30) Foreign Application Priority Data
Sep. 30, 2002 (EP) 02079032.5

(51) Int. Cl. H03M 3/00

(52) U.S. Cl. 341/143

(57) ABSTRACT

Sigma-delta modulation is provided, wherein an input signal is feeded to at least two parallel filters, a first one of the filters preferably being a lower order filter and a second one of the filters preferably being a higher order filter, wherein output of the filters are weighted and wherein the weighted output from the at least two filters is quantized, in order to enable a sigma-delta modulation with variable order.

### BACKGROUND OF THE INVENTION

1. Field of the Invention

The present invention generally relates to sigma-delta modulation.

2. Description of the Related Art

WO 02/21526 addresses the problem of increasing the compression ratio of a bitstream signal. Further, WO 98/20488 and WO 98/16014 increase the compression ratio obtained by the Direct Stream Transfer (DST) algorithm used in the Super Audio Compact Disc (SACD) standard using an adaptive sigma-delta modulator (SDM) to adjust the compression of a bitstream signal by adjusting the parameters of the SDM. As illustrated in FIG. 1, an analog signal 10 is provided to A/D converter 12 and a multi-bit digital signal 14 is output. As an example, the A/D converter 12 has characteristics of 256 fs and noise-free bandwidth of 80 kHz. The multi-bit digital signal 14 is input to a DD converter 16, which includes a low pass filter (LPF) 20 and a sigma-delta modulator 22. As an example, the output signal 24 of the DD converter 16 is 64 fs and 1-bit, which is the direct stream digital (DSD) format.

FIG. 2 illustrates the basic structure of a conventional SDM 22. The SDM 22 includes an adder 12, a loopfilter 14, and a quantizer 16. SDMs may be implemented as analog or digital SDMs.

A conventional technique for increasing compression ratio includes changing the order of the SDM 22. This has the practical disadvantage that switching between outputs of these modulators becomes necessary, and therefore continuous variation of the compression ratio is not possible.

Another way of adjusting the SDM 22 is to change the coefficients of the SDM 22. FIG. 3 illustrates a conventional topology for a feedforward SDM 30. As illustrated, the feedforward SDM 30 is a fourth order SDM which includes four delay elements T₁-T₄, four coefficients c₁-c₄, adders 34 and 38 and a quantizer 36. A change to lower or higher SDM structures can be made by removing or adding delay elements Tₙ or coefficients cₙ. It might be expected that reducing the last coefficients to zero, should give a stable lower order SDM. However, this is not easily accomplished because the resulting modulator may not always be stable. As a result, the stability requirement substantially restricts the freedom in choice of loopfilters of an SDM.

### SUMMARY OF THE INVENTION

An object of the invention is to provide advantageous sigma-delta modulation.

To this end, the present invention provides a sigma-delta modulator (SDM) and a method wherein the sigma-delta modulation can change order. The SDM remains stable during change in order. Such an SDM may be used to influence compression gain in a DST algorithm.

Advantageous embodiments are defined in the dependent claims.

In an exemplary embodiment, the SDM includes a parallel realization of a filter H(z) and a filter L(z), where, for example, H is a high order filter (giving low compression ratios) and L is a low order filter. An amplifier can vary the weight of the filter H with respect to the filter L. These filters can be designed such, that any linear (parallel) combination of these filters will result in stable operation of the SDM, while still maintaining many degrees of freedom for the choice of filters. This in turn allows a balance between the reduction in audio quality and the increase in compression ratio.

In yet another preferred embodiment, the device for improving compression ratio is a noise shaper.

Advantages of the present invention will become more apparent from the detailed description provided hereafter. However, it should be understood that the detailed description and specific examples, while indicating preferred embodiments of the present invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given below and the accompanying drawings, which are given for purposes of illustration only, and thus do not limit the invention.

FIG. 1 illustrates a conventional device.

FIG. 2 illustrates the basic structure of a conventional SDM.

FIG. 3 illustrates a topology for a conventional feedforward SDM.

FIG. 4 illustrates an SDM in an exemplary embodiment of the present invention.

FIG. 5 is a graph illustrating the effect of mixing between a third and fifth order SDM.

FIG. 6 illustrates a noise shaper in another exemplary embodiment of the present invention.

FIG. 7 illustrates a cascade of SDMs illustrated in FIG. 4 in one exemplary embodiment of the present invention.

FIG. 8 illustrates an SDM device with the output from the SDM of FIG. 7.

FIG. 9 illustrates an SDM device, in another exemplary embodiment of the present invention.

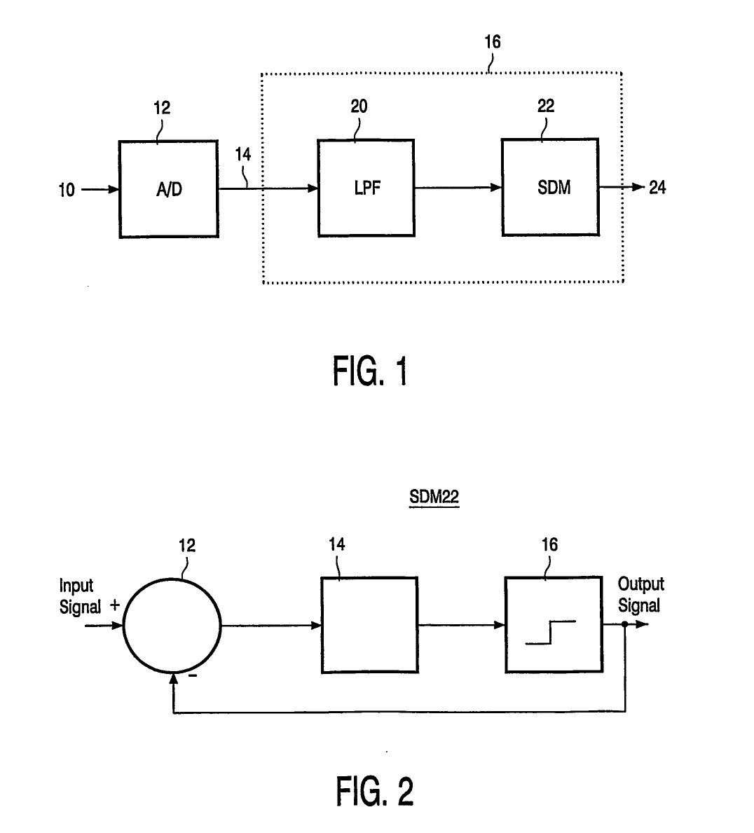

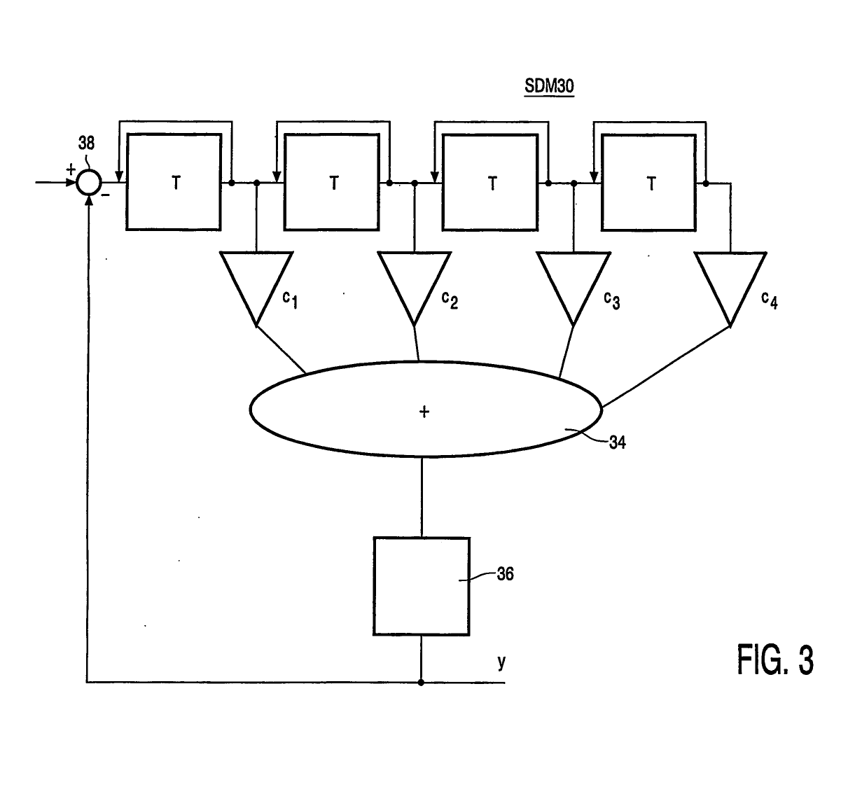

### DETAILED DESCRIPTION OF THE EXEMPLARY EMBODIMENTS

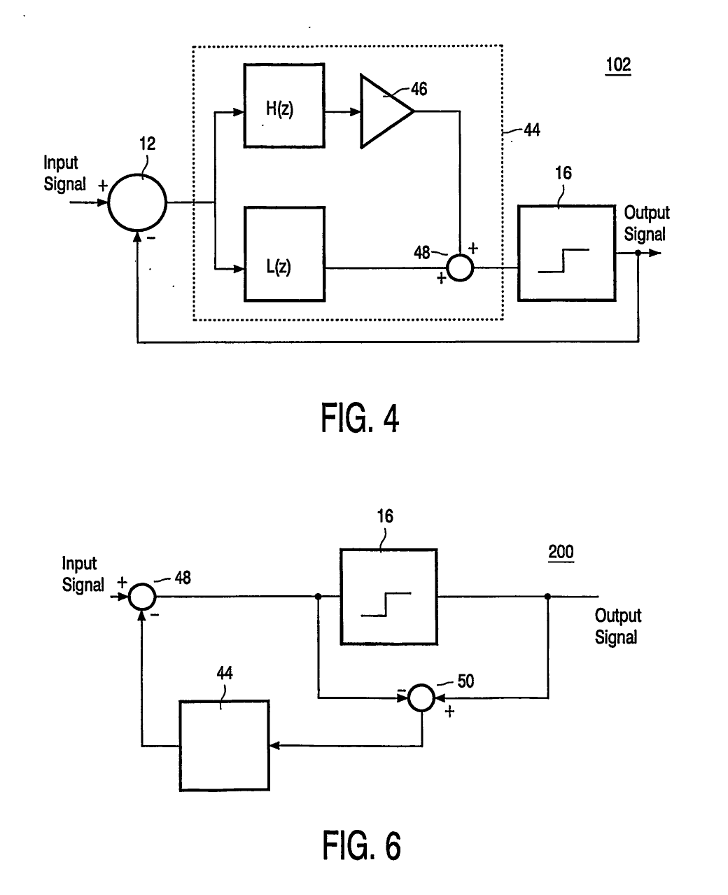

FIG. 4 illustrates an adaptive SDM 102 in an exemplary embodiment of the present invention. As illustrated, the adaptive SDM 102 includes an adder 12, a loopfilter 44, and a quantizer 16. The loopfilter 44 includes at least two filters H(z) and L(z), where, for example, H(z) is a high order filter (giving low compression ratios) and L(z) is a low order filter, an adder 48 and an amplifier 46. The amplifier 46 can vary the weight of the filter H(z) with respect to the filter L(z). These filters can be designed such, that any linear (parallel) combination of these filters will result in stable operation of the adaptive SDM 102, until the noise shaping of the SDM 102 becomes too aggressive, as people skilled in the art know. Still many degrees of freedom exists for the choice of filters. This in turn gives the possibility to balance the reduction in audio quality against the increase in compression ratio.

As an example, consider a third order loopfilter for L(z) (characterized by c₁=0.69; c₂=0.183; C₃=0.016 in FIG. 4) and a fifth order for H(z) (characterized by c₁=0.00300; c₂=0.00267; c₃=0.00105; c₄=0.000222; c₅=0.0000189; in FIG. 4).

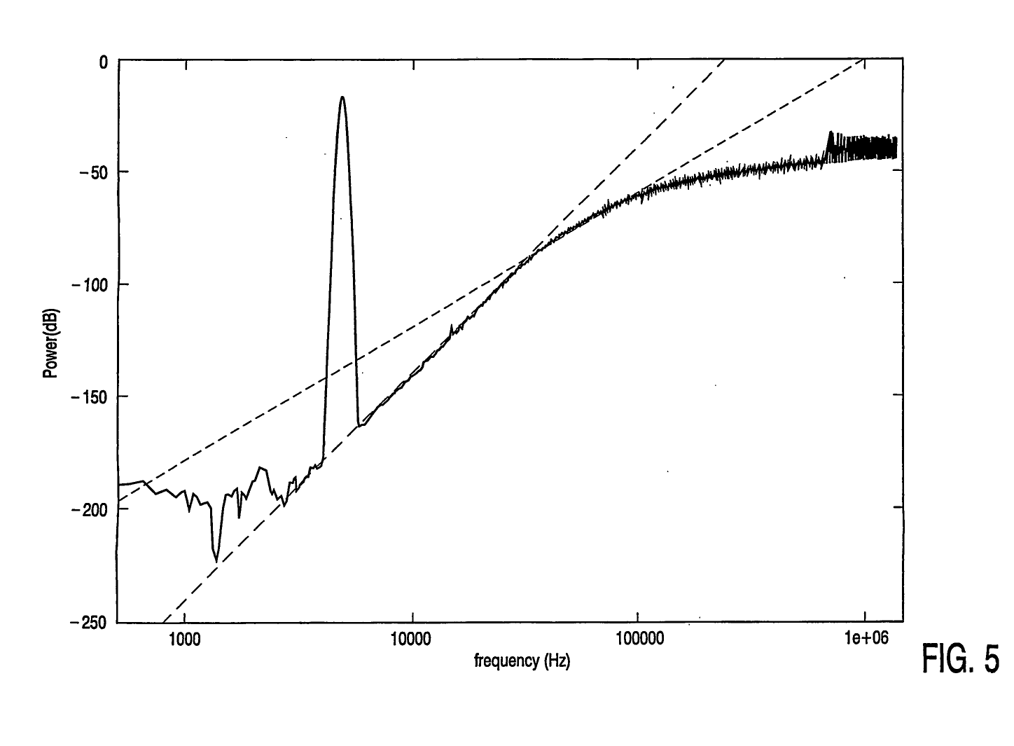

The resulting power spectrum for a −6 dB input is illustrated in FIG. 5. From FIG. 5, it can clearly be observed, that between about 140 and 40 kHz, the SDM 102 behaves as third order; below 40 kHz the SDM 102 becomes fifth order. The exact position where this cross-over occurs depends on the amplifier 46 in FIG. 4.

It is noted that although one of the general concepts of the present invention has been applied to an SDM in the embodiment of FIGS. 4-5, this concept could also be applied to other structures as would be known to one of ordinary skill in the art. For example, the general concept described in conjunction with FIGS. 4-5 could also be applied to a noise shaper, as illustrated in FIG. 6. As illustrated, the noise shaper 200 includes a loopfilter with the same function as 44 of FIG. 4, quantizer 16, and two subtractors 48,50.

Low order SDM modulators have the undesirable characteristic of displaying (sometimes) audible tones, and harmonic distortion. It is conceivable that when the setting of the amplifier 46 is such that the resulting SDM 102 (or noise shaper 200) is foremost third order, it will inherit these characteristics. Replacing a single SDM (or noise shaper) by a cascade of two or more SDM's (or noise shapers) reduces this drawback. A filter/delay pair is placed between each adjacent pair of SDMs (or noise shapers). The combination of the cascaded SDMs (or noise shapers) and the filter/delay pair(s) reduce amplitude errors in the output bitstream. A filter may also be placed in parallel with at least one SDM (or noise shapers). The parallel filter(s) reduces phase shift errors in the output bitstream.

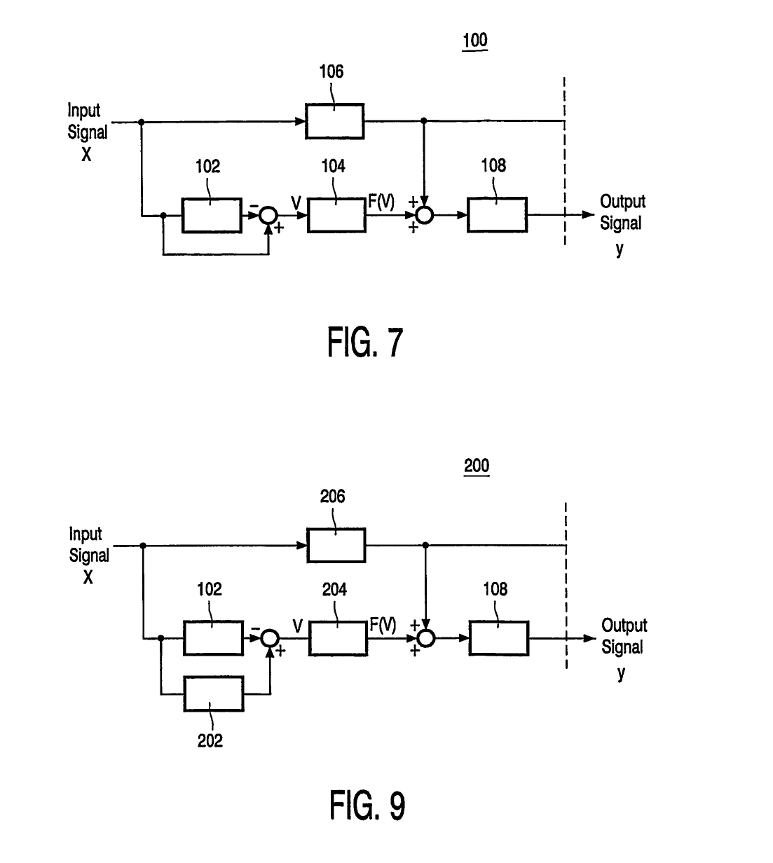

An exemplary SDM device 100, which accomplishes this model in the digital domain, is show in FIG. 7. The SDM device 100 includes a first SDM 102, a filter 104, a delay 106, and a second SDM 108.

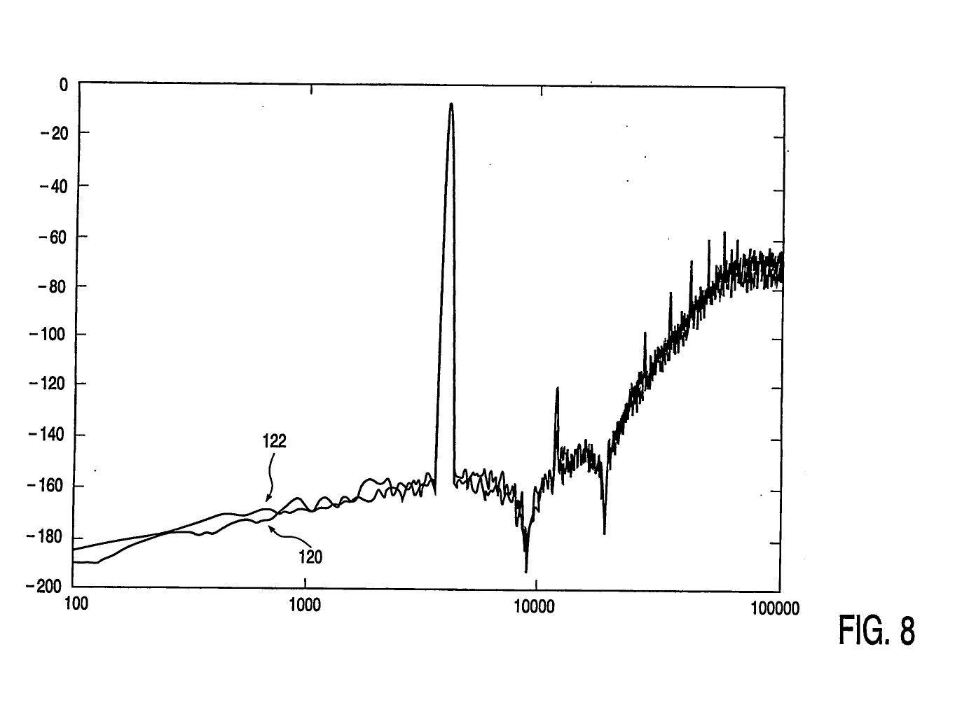

An exemplary output of the SDM device 100 of FIG. 7 is illustrated in FIG. 8, where 120 is the output signal from a single conventional, low-order, undithered, SDM and 122 is the output from the cascade of SDMs of FIG. 7. The improvement is clear.

It is noted that the SDM device 100 of FIG. 7 includes two cascaded SDMs, however more SDMs could also be cascaded to further reduce residual terms. It is further noted that the cascade of two or more SDMs may be identical SDMs.

It is further noted that although the SDM device 100 of FIG. 7 reduces for amplitude errors, it is also possible to reduce phase shift errors. These phase shift errors may be corrected as illustrated in the exemplary embodiment of FIG. 9.

In the exemplary embodiment of FIG. 9, the SDM device 200 includes a filter 202 to correct for a (frequency dependent) phase rotation of the input signal to filter 204. The filter 204 has a lowpass characteristic to reduce the high frequency noise. Finally, a delay 206 is used to compensate for all delays. The delays may be a non-integer fraction of the time step (in the digital domain), therefore, delay 206 might be more complicated than a sequence of flip-flops, but still within the skill of an ordinary artisan.

It is further noted that the processing described above is particular useful in the processing of DSD.

It is further noted that that the input need not be restricted to a bitstream; the input may also be a (multi-bit) low-pass filtered bitstream.

It is further noted that the features of the present invention are usable with many types of SDMS, including analog, digital, SC-filter, dithered, undithered, low order, high order, single-bit, multi-bit or any combination of these features, as well as other devices such as noise shapers, either in combination with SDMs and/or other devices or alone.

The device according to embodiments of the invention may be included in a signal processing apparatus. Such an apparatus may be (part of) SACD equipment, e.g. a player. The apparatus may further be a DSD-AD converter, etc.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claims. The word “comprising” does not exclude the presence of other elements or steps than those listed in a claim. The invention can be implemented by means of hardware comprising several distinct elements, and by means of a suitable programmed computer. In a device claim enumerating several means, several of these means can be embodied by one and the same item of hardware. The mere factor that certain measures are recited in mutually different dependent claims does not indicate that a combination of these measures cannot be used to advantage.

In summary, sigma-delta modulation is provided, wherein an input signal is feeded to at least two parallel filters, a first one of the filters preferably being a lower order filter and a second one of the filters preferably being a higher order filter, wherein output of the filters are weighted and wherein the weighted output from the at least two filters is quantized, in order to enable a sigma-delta modulation with variable order.

1. A sigma-delta modulator, comprising:
at least two parallel filters, each receiving an input signal
a gain device for controlling a weight associated with an output of each of the at least two parallel filters, and
a quantizer for quantizing a weighted output from said gain device.

2. The sigma-delta modulator of claim 1, wherein an output of said quantizer is fed back as an input to said at least two parallel filters.

3. The sigma-delta modulator of claim 1, wherein at least one of said at least two parallel filters is a high order filter and at least one of said at least two parallel filters is a low order filter.

4. A method of sigma-delta modulation, comprising:
inputting a signal to at least two parallel filters,
controlling a weight associated with an output of each of the at least two parallel filters, and
quantizing a weighted output from the at least two parallel filters.

5. The method of claim 4, wherein an output of said quantizing is fed back as an input to the at least two parallel filters.

6. The method of claim 4, wherein at least one of the at least two parallel filters is a high order filter and at least one of the at least two parallel filters is a low order filter.

7. A signal processing apparatus comprising:
an input for obtaining an input signal, a sigma-delta modulator as claimed claim 1, and
an output unit for providing said output signal.
